(19) United States
(12) Patent Application Publication
(10) Pub. No.: US 2012/0205777 A1
(43) Pub. Date: Aug. 16, 2012

(54) SEMICONDUCTOR DEVICE AND METHOD FOR FABRICATING THE SAME

(76) Inventor: Sang-Hyun LEE, Gyeonggi-do (KR)

(21) Appl. No.: 13/338,556

(22) Filed: Dec. 28, 2011

(30) Foreign Application Priority Data
Feb. 14, 2011 (KR) 10-2011-0012775

(51) Int. Cl. H01L 29/06; H01L 21/76

(52) U.S. Cl. 257/508; 438/435; 257/E29.02; 257/E21.54

(57) ABSTRACT

A semiconductor device includes a trench formed in a substrate and defining a plurality of active regions, a punch-through prevention layer filling a part of the trench and coupled to a ground, and an isolation layer formed over the punch-through prevention layer and filling the other part of the trench.

### CROSS-REFERENCE TO RELATED APPLICATIONS

The present application claims priority of Korean Patent Application No. 10-2011-0012775, filed on Feb. 14, 2011, which is incorporated herein by reference in its entirety.

### BACKGROUND

1. Field

Exemplary embodiments of the present invention relate to fabrication technology of a semiconductor device, and more particularly, to a semiconductor device capable of preventing a punch-through from occurring between adjacent active regions and a method for fabricating the same.

2. Description of the Related Art

As the design rule has been decreased with the high integration of the semiconductor devices, a shallow trench isolation (STI) process has been used to form an isolation layer which electrically isolates adjacent active regions.

FIG. 1 is a cross-sectional view of a conventional semiconductor device.

Referring to FIG. 1, the conventional semiconductor device includes an isolation trench 12 defining a plurality of active regions 13 in a substrate 11, a stacked layer in which a wall oxide 14, a liner nitride 15, and a liner oxide 16 are sequentially stacked along the surface of the trench 12, and an isolation layer 17 formed over the liner oxide 16 and filling the trench 12.

In the conventional semiconductor device, electric charges are trapped in the liner nitride 15 due to the nature of the liner nitride 15 and interfacial properties between the wall oxide 14 and the liner nitride 15. The electric charges trapped in the liner nitride 15 form a conduction path along the interface between the trench 12 and the substrate 11. Then, a punch-through may occur between adjacent active regions 13 due to the conduction path formed by the electric charges. For reference, the punch-though refers to an extreme case in channel length of a MOSFET where the depletion layers around the active regions, i.e., drain and source regions, merge into a single depletion region. It may cause a rapidly increasing current with increasing drain-source voltage.

### SUMMARY

Exemplary embodiments of the present invention are directed to a semiconductor device capable of preventing a punch-through from occurring between adjacent active regions and a method for fabricating the same.

In accordance with an exemplary embodiment of the present invention, a semiconductor device includes a trench formed in a substrate and defining a plurality of active regions, a punch-through prevention layer filling a part of the trench and coupled to a ground and an isolation layer formed over the punch-through prevention layer and filling the other part of the trench.

The semiconductor device may further include a ground line formed over the substrate and a plug formed through the isolation layer and electrically coupling the ground line and the punch-through prevention layer.

The semiconductor device may further include a liner layer formed on a sidewall of the trench.

In accordance with another exemplary embodiment of the present invention, a method for fabricating a semiconductor device includes forming a trench defining a plurality of active regions in a substrate, forming a punch-through prevention layer to fill a part of the trench, forming an isolation layer over the punch-through prevention layer to fill the other part of the trench, forming a plug to be coupled to the punch-through prevention layer by passing through the isolation layer, and forming a ground line over the substrate to be coupled to the plug.

The method may further include forming a liner layer along the trench surface and selectively etching the liner layer to expose the bottom surface of the trench.

### BRIEF DESCRIPTION OF THE DRAWINGS

FIG. 1 is a cross-sectional view of a conventional semiconductor device.

FIG. 2 is a diagram illustrating a semiconductor device in accordance with an exemplary embodiment of the present invention.

FIGS. 3A to 3E are cross-sectional views illustrating a method for fabricating the semiconductor device in accordance with the exemplary embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

The embodiments of the present invention provide a semiconductor device capable of preventing a punch-through from occurring between adjacent active regions and a method for fabricating the same. In general, a method of increasing the distance between active regions or a method of performing punch-through stop ion-implantation under the surface of an isolation trench is used to prevent a punch-through from occurring between adjacent active regions. However, with the increase in integration degree of semiconductor devices, the method of increasing the distance between active regions may not be substantially applied any more. Furthermore, since the punch-through stop ion-implantation uses high implantation energy, a substrate may be damaged by implantation, thereby degrading properties of a semiconductor device. In the embodiments of the present invention, a punch-through prevention layer coupled to a ground line is formed in a lower region of an isolation trench so as to prevent a conduction path causing a punch-through from being formed along the interface between the trench and the substrate. Therefore, a punch-through may be effectively prevented from occurring between adjacent active regions, even though the integration degree of the semiconductor device increases.

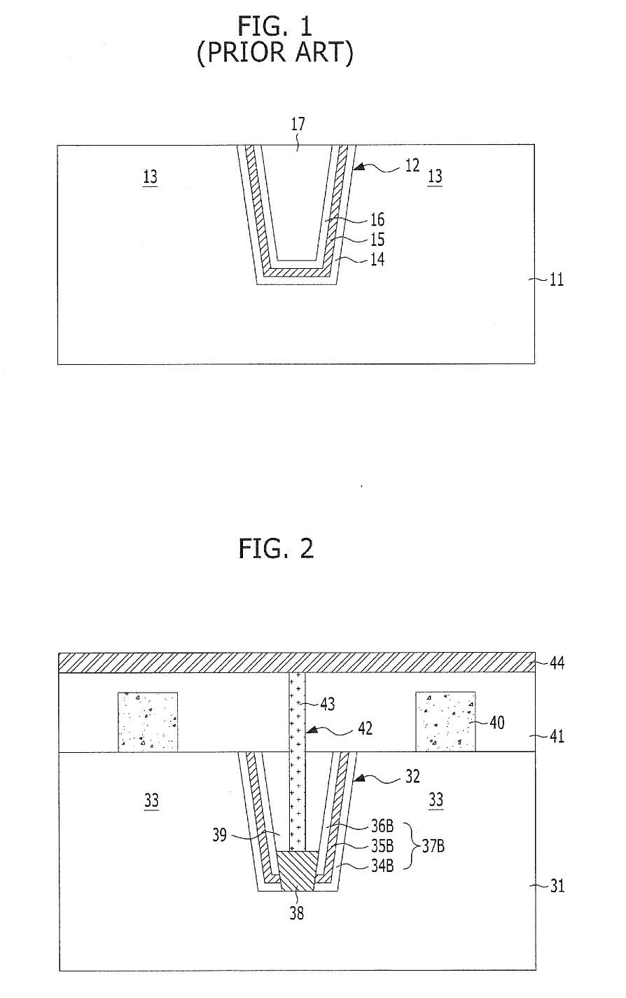

FIG. 2 is a diagram illustrating a semiconductor device in accordance with an embodiment of the present invention.

Referring to FIG. 2, the semiconductor device in accordance with the embodiment of the present invention includes an isolation trench 32 formed in a semiconductor substrate 31, for example, a silicon substrate, and defining a plurality of active regions 33, a liner layer 37B formed on the sidewalls of the trench 32, a punch-through prevention layer 38 filling a part of the trench 32 and coupled to a ground line 44 so as to have a ground potential during operation, and an isolation layer 39 formed over the punch-through prevention layer 38 and filling the other part of the trench 32. Furthermore, the semiconductor device may include a predetermined structure formed over the substrate 31, for example, a gate 40, an interlayer dielectric layer 41 formed on the entire surface of the substrate 31 and covering the gate 40, the ground line 44 formed over the interlayer dielectric layer 41, and a plug 43 passing through the interlayer dielectric layer 41 and the isolation layer 39 and electrically coupling the ground line 44 and the punch-through prevention layer 38. In this embodiment of the present invention, the gate 40 is taken as an example of the predetermined structure formed over the substrate 31, for the purpose of description. However, the semiconductor device may further include other structures (for example, bit line, capacitor, and so on), in addition to the gate 40.

The liner layer 37B formed on the sidewalls of the trench 32 may have a structure in which a wall oxide 34B, a liner nitride 35B, and a liner oxide 36B are sequentially stacked. The wall oxide 34B serves to cure a substrate damage occurring while forming the trench 32. The liner nitride 35B serves to protect the wall oxide 34B, prevent impurities of the active regions 33 from permeating into the trench 32, and relieve a stress of the isolation layer 39. The liner oxide 36B serves to improve interfacial properties between the liner nitride 35B and the isolation layer 39.

The punch-through prevention layer 38 serves to prevent a conduction path, which causes a punch-through, from being formed along the interface between the trench 32 and the substrate 31 by electric charges trapped in the liner nitride 35B due to the nature of the liner nitride 35B and interfacial properties between the wall oxide 34B and the liner nitride 35B. For this operation, the punch-through prevention layer 38 is positioned in a lower region of the trench 32 so as to be in contact with the substrate 31 and has a level of a ground voltage during operation. This is because the punch-through prevention layer 38 is electrically coupled to the ground line 44 through the plug 43. Here, the ground line 44 means a conductive line to which a ground voltage is applied during the operation and may include a metal interconnection.

Since the punch-through prevention layer 38 has such a structure that is in contact with the substrate 31, the liner nitride 35B does not remain between the punch-through prevention layer 38 and the substrate 31. Therefore, electric charges may be prevented from being trapped therebetween. Furthermore, since the punch-through prevention layer 38 always has a ground voltage level during operation, a conduction path causing a punch-through may be prevented from being formed in the region where the punch-through prevention layer 38 and the substrate 31 are in contact with each other.

The punch-through prevention layer 38 includes a conductive layer, and a semiconductor conductive layer may be used as the conductive layer. At this time, the semiconductor conductive layer may include an impurity-undoped semiconductor conductive layer.

Specifically, the semiconductor conductive layer includes a silicon layer, and the silicon layer may include an impurity-undoped silicon layer. Here, the reason why the undoped silicon layer is used is as follows. As described above, the punch-through prevention layer 38 has a structure that is in contact with the substrate 31. Therefore, when a doped silicon layer is used, impurities doped in the silicon layer may be diffused into the substrate 31. Accordingly, when the undoped silicon layer is used, the degradation of the semiconductor device may be prevented from being caused by the diffusion of impurities.

Meanwhile, a metallic conductive layer including metal has a more excellent electric characteristic than a semiconductor conductive layer. However, since the punch-through prevention layer 38 is in contact with the substrate 31, the punch-through prevention layer 38 may be formed of a semiconductor conductive layer, instead of a metallic conductive layer. That is because, when a metallic conductive layer is in contact with the substrate 31, metal elements contained in the metallic conductive layer may be easily diffused into the substrate 31 due to a large mobility of the metal elements, and thus the properties of the semiconductor device may be degraded by the metal elements diffused into the substrate 31.

The plug 43 passing through the interlayer dielectric layer 41 and the isolation layer 39 and electrically coupling the ground line 44 and the punch-through prevention layer 38 may be formed by the following series of processes: the interlayer dielectric layer 41 and the isolation layer 39 are simultaneously etched to form a contact hole 42 exposing the punch-through prevention layer 38, and a conductive layer is then buried in the contact hole 42. Alternatively, the plug 43 may be formed by the following process: a first plug (not illustrated) is formed through the isolation layer 39, and a second plug (not illustrated) coupled to the first plug by passing through the interlayer dielectric layer 41 is then formed, in order to easily perform an etching process.

The semiconductor device having the above-described structure in accordance with the embodiment of the present invention includes the punch-through prevention layer 38 having a ground voltage level during operation, which is formed in the lower region of the trench 32, thereby preventing a punch-through from occurring between adjacent active regions 33. Therefore, since the distance between the active regions 33 may be further reduced, the integration degree of the semiconductor device may increase. Furthermore, since the punch-through stop ion-implantation may be omitted, the degradation of the semiconductor device may be prevented from being caused by a substrate damage which may occur during implantation.

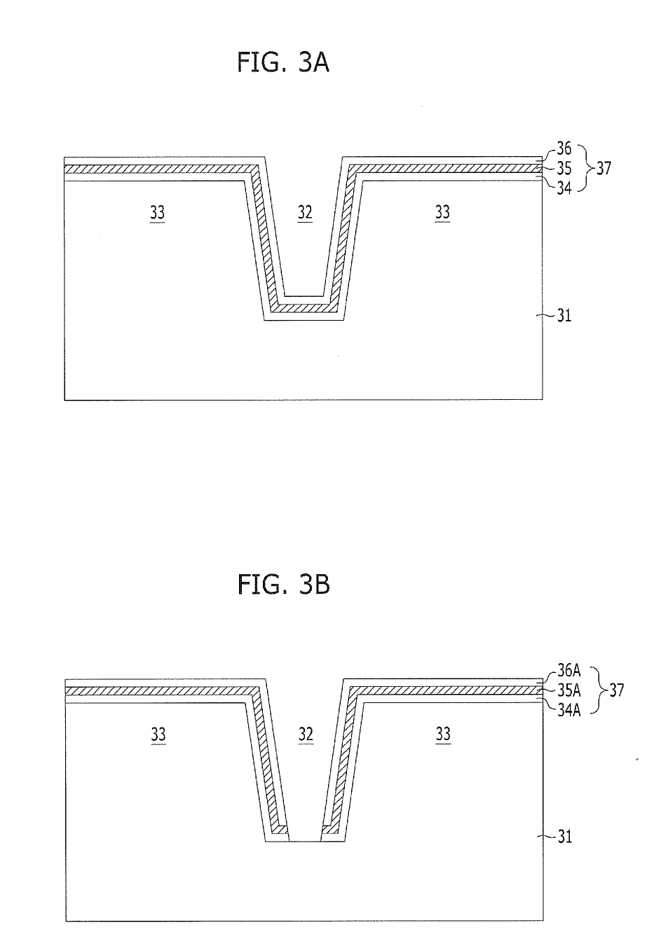

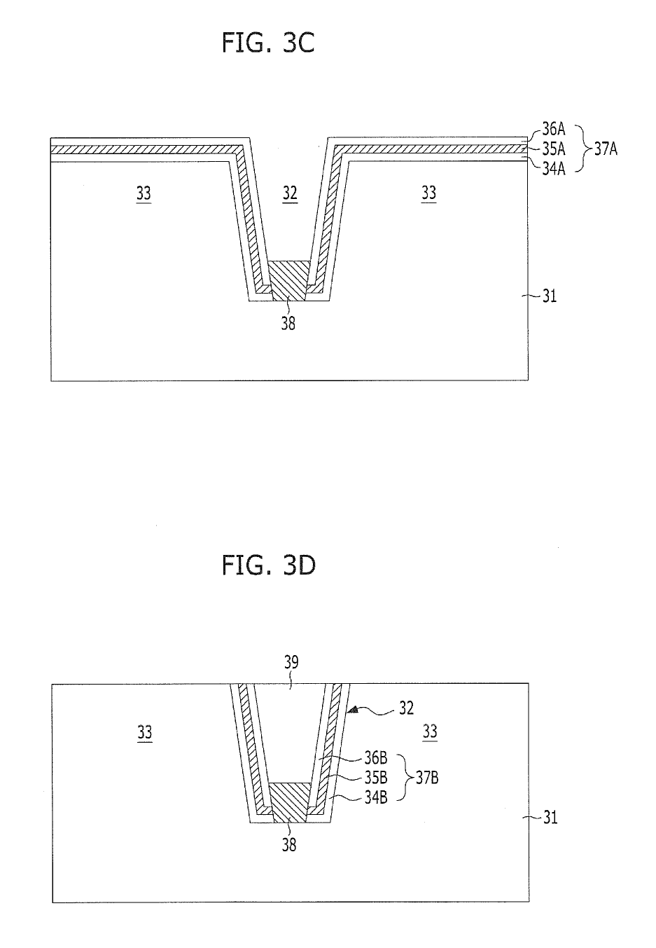

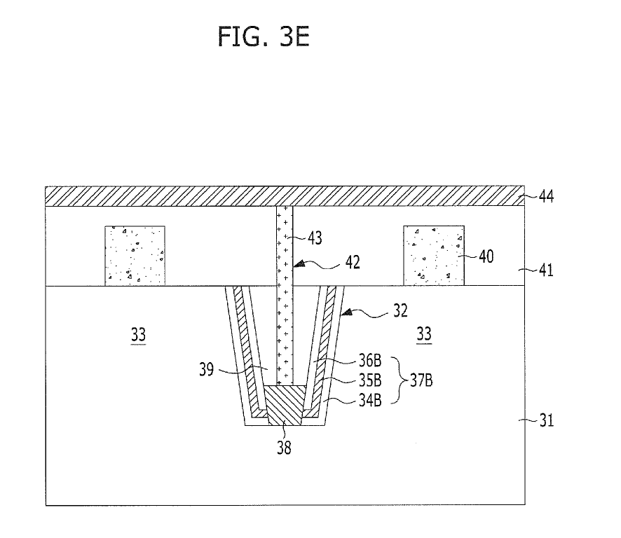

FIGS. 3A to 3E are cross-sectional views illustrating a method for fabricating the semiconductor device in accordance with the embodiment of the present invention.

Referring to FIG. 3A, an isolation trench 32 defining a plurality of active regions 33 is formed in a semiconductor substrate 31, for example, a silicon substrate. The trench 32 may be formed by a dry etching process.

A liner layer 37 is formed along the surface of the substrate 31 including the trench 32. The liner layer 37 may include a stacked layer in which a wall oxide 34, a liner nitride 35, and a liner oxide 36 are sequentially stacked. The wall oxide 34 serves to cure a substrate damage occurring while forming the trench 32 and may be formed by a thermal oxidation method. The liner nitride 35 serves to protect the wall oxide 34, prevent impurities of the active regions 33 from diffusing into the trench 32, and relieve a stress of an isolation layer which is to be formed through a subsequent process. The liner oxide 36 serves to improve interfacial properties between the liner nitride 35 and the isolation layer.

Referring to FIG. 3B, the liner layer 37 is selectively etched to expose the substrate 31 at the bottom surface of the trench 32. Here, the etching of the liner layer 37 may be performed by the following process: a photoresist pattern (not illustrated) is formed to expose the liner layer 37 formed on the bottom surface of the trench 32, and the liner layer 37 is etched using the photoresist pattern as an etch barrier until the substrate 31 is exposed. Alternatively, a blanket process, for example, an etch-back process may be performed to etch the liner layer 37 such that the liner layer 37 remains in a spacer form on the sidewalls of the trench 32.

Hereafter, reference numerals of the wall oxide 34, the liner nitride 35, the liner oxide 36, and the liner layer 37, which are etched to expose the substrate 31 at the bottom surface of the trench 32, are changed into 34A, 35A, 36A, and 37A, respectively.

Referring to FIG. 3C, a punch-through prevention layer 38 is formed to fill a part of the trench 32. The punch-through prevention layer 38 serves to prevent a punch-through from occurring between adjacent active regions 33 and may be formed of a conductive layer. Specifically, the punch-through prevention layer 38 may be formed of a semiconductor conductive layer, and a silicon layer may be used as the semiconductor conductive layer. At this time, the punch-through prevention layer 38 may be formed of an impurity-undoped silicon layer.

When the punch-through prevention layer 38 filling a part of the trench 32 is formed of a silicon layer, the punch-through prevention layer 38 may be formed by an epitaxial growth method using the surface of the substrate 31 exposed through the trench 32 as a seed, or it may be formed by a method of forming a silicon layer to fill the trench 32 and performing a blanket process, for example, an etch-back process such that the silicon layer partially remains in the trench 32.

Referring to FIG. 3D, an isolation dielectric layer is formed over the entire surface of the resultant structure including the punch-through prevention layer 38 so as to fill the other part of the trench 32. At this time, the dielectric layer may be formed of oxide.

A planarization process is performed until the substrate 31 is exposed. Then, an isolation layer 39 filling the other part of the trench 32 is formed over the punch-through prevention layer 38. At this time, the planarization process may include chemical mechanical polishing (CMP). As the planarization process is performed, the liner layer 37A remains only on the sidewalls of the trench 32.

Hereafter, reference numerals of the wall oxide 34A, the liner nitride 35A, the liner oxide 36A, and the liner layer 37A, which remain on the sidewalls of the trench 32, are changed into 34B, 35B, 36B, and 37B, respectively.

Referring to FIG. 3E, a predetermined structure, for example, a gate 40 is formed over the substrate 31. For reference, in this embodiment of the present invention, the gate 40 is taken as an example of the predetermined structure which is formed over the substrate 31 after the isolation layer 39 is formed. However, other structures (for example, bit line, capacitor and so on) may be formed, in addition to the gate 40.

An interlayer dielectric layer 41 is formed over the entire surface of the substrate 31 so as to cover the gate 40.

The interlayer dielectric layer 41 and the isolation layer 39 are selectively etched to form a contact hole 42 exposing the punch-through prevention layer 38. The contact hole 42 may be formed by a dry etching process.

A plug 43 is formed to fill the contact hole 42, and a ground line 44 is formed over the interlayer dielectric layer 41 so as to be coupled with the plug 43. At this time, the ground line 44 indicates a conductive line to which a ground voltage is applied and may include a metal interconnection. As the punch-through prevention layer 38 and the ground line 44 are electrically coupled through the plug 43, the punch-through prevention layer 38 has a state that a ground voltage is applied during operation.

In the above-described method for fabricating a semiconductor device in accordance with the embodiment of the present invention, the punch-through prevention layer 38 having a ground voltage during operation is formed in the lower region of the isolation trench 32. Therefore, the formation of a conduction path causing a punch-through may be prevented, which may prevent a punch-through from occurring between the adjacent active regions 33.

While the present invention has been described with respect to the specific embodiments, it will be apparent to those skilled in the art that various changes and modifications may be made without departing from the spirit and scope of the invention as defined in the following claims.

What is claimed is:

1. A semiconductor device comprising:
a trench formed in a substrate and defining a plurality of active regions;
a punch-through prevention layer filling a part of the trench and coupled to a ground; and
an isolation layer formed over the punch-through prevention layer and filling the other part of the trench.

2. The semiconductor device of claim 1, further comprising:
a ground line formed over the substrate; and
a plug formed through the isolation layer and electrically coupling the ground line and the punch-through prevention layer.

3. The semiconductor device of claim 1, further comprising a liner layer formed on a sidewall of the trench.

4. The semiconductor device of claim 3, wherein the liner layer has a stacked structure in which a wall oxide, a liner nitride, and a liner oxide are sequentially stacked.

5. The semiconductor device of claim 1, wherein the punch-through prevention layer is formed in a lower region of the trench and in contact with the substrate.

6. The semiconductor device of claim 1, wherein the punch-through prevention layer comprises a semiconductor conductive layer.

7. The semiconductor device of claim 1, wherein the punch-through prevention layer comprises a silicon layer.

8. The semiconductor device of claim 1, wherein the punch-through prevention layer comprises an undoped silicon layer.

9. A method for fabricating a semiconductor device, comprising:
forming a trench defining a plurality of active regions in a substrate;
forming a punch-through prevention layer to fill a part of the trench;
forming an isolation layer over the punch-through prevention layer to fill the other part of the trench;
forming a plug to be coupled to the punch-through prevention layer by passing through the isolation layer; and
forming a ground line over the substrate to be coupled to the plug.

10. The method of claim 9, further comprising, before the forming of the punch-through prevention layer:
forming a liner layer along the surface of the trench; and
selectively etching the liner layer to expose the bottom surface of the trench.

11. The method of claim 10, wherein the liner layer is formed of a stacked layer in which a wall oxide, a liner nitride, and a liner oxide are sequentially stacked.

12. The method of claim 10, wherein the etching of the liner layer comprises:
forming a photoresist pattern over the liner layer to expose the liner layer formed on the bottom surface of the trench; and
etching the liner layer using the photoresist pattern as an etch barrier, until the substrate is exposed at the bottom surface of the trench.

13. The method of claim 10, wherein the etching of the liner layer comprises performing a blanket process until the substrate at the bottom surface of the trench is exposed.

14. The method of claim 9, wherein the punch-through prevention layer comprises a semiconductor conductive layer.

15. The method of claim 9, wherein the punch-through prevention layer comprises a silicon layer.

16. The method of claim 9, wherein the punch-through prevention layer comprises an undoped silicon layer.
